(19) United States
(12) Patent Application Publication
(10) Pub. No.: US 2012/0228580 A1
(43) Pub. Date: Sep. 13, 2012

(54) LIGHT-EMITTING DIODE DEVICE AND METHOD FOR MANUFACTURING THE SAME

(75) Inventors: Hsin Chuan Wang, Tainan City (TW); Hao Ching Wu, Tainan City (TW)

(73) Assignee: CHI MEI LIGHTING TECHNOLOGY CORP., Tainan City (TW)

(21) Appl. No.: 13/164,251

(22) Filed: Jun. 20, 2011

(30) Foreign Application Priority Data
Mar. 11, 2011 (TW) 100108343

(51) Int. Cl. H01L 33/06; H01L 33/14

(52) U.S. Cl. 257/13; 438/47; 257/E33.01; 257/E33.012

(57) ABSTRACT

A light-emitting diode device and a method for manufacturing the same. In one embodiment, the light-emitting diode device comprises a substrate, an undoped semiconductor layer and a current blocking structure disposed on the substrate in sequence, a plurality of light-emitting structures, separately disposed on the current blocking structure, a plurality of insulating spacers, respectively located between the adjacent light-emitting structures, and a plurality of conductive wires. Each of the light-emitting structures has a first conductivity type semiconductor layer, an active layer, a second conductivity type semiconductor layer, and a first electrode and a second electrode. The first conductivity type semiconductor layer and the second conductivity type semiconductor layer have different conductivity types. The plurality of conductive wires respectively connecting the first electrode of one of the adjacent light-emitting structures and the second electrode of the other light-emitting structure in sequence.

### CROSS-REFERENCE TO RELATED APPLICATION

This non-provisional application claims priority under 35 U.S.C. §119(a) on Patent Application No. 100108343 filed in Taiwan, R.O.C. on Mar. 11, 2011, the entire contents of which are hereby incorporated by reference.

### FIELD OF THE INVENTION

The present invention relates to a light-emitting device, and more particularly to a light-emitting diode (LED) device and method for manufacturing the same.

### BACKGROUND OF THE INVENTION

Along with the vigorous development of the LED technique and the advantages such as a thin volume, power saving and mercury free of the LED applied in the light sources, the LED technique is in the trend of gradually replacing the traditional light-emitting technique.

Also, with the increase of the proportion of LED applications in high luminous products like illuminators and headlights of vehicles, the requirements for the luminance of the LED chip gradually increase. To obtain a higher luminance, in operation, a larger driving current is required so as to increase the luminance of the LED chip.

However, the increase of the current probably induces a distinct decrease of the luminous efficiency along with the increase of the injected current, which produces the so-called efficiency droop phenomenon. That is to say, under the circumstance that a high current is continuously injected, the carriers that contribute to emitting light are provided, but the luminous efficiency of the LED device is not improved and contrarily, the luminous efficiency is in the trend of decreasing. Currently, in order to avoid the efficiency droop phenomenon, usually, the dimension of the LED chip is increased to improve the luminance. However, the increase of the dimension of the LED chip causes a non-uniform current spreading problem.

Generally speaking, as shown in FIG. 1A, the driving current of the low-power LED chip 100 is low and the current spreading effect is good. Therefore, the injected current can be uniformly spread in the LED chip 100 without particularly designing the arrangement and shape of the n-type contact electrode 102 and the p-type contact electrode 104, thereby achieving a uniform light-emitting effect. The LED chip 110 in FIG. 1B and the LED chip 120 in FIG. 1C are high-power LED chips having different dimensions. Here, the dimension of the LED chip 100 in FIG. 1A is smaller than that of the LED chip 110 in FIG. 1B, and the dimension of the LED chip 110 in FIG. 1B is smaller than that of the LED chip 120 in FIG. 1C. The driving current of the high-power LED chips in FIG. 1B and FIG. 1C are large. Currently, in addition to increasing the dimension of the LED chip to alleviate the efficiency droop phenomenon and increase the heat dissipation area, p-type and n-type contact electrodes with conductive fingers are disposed, and thus a parallel circuit concept is employed to improve the current spreading. For example, the p-type contact electrode 114 of the LED chip 110 has a conductive finger 116 extending towards the n-type contact electrode 112. The p-type contact electrode 124 of the LED chip 120 has three conductive fingers 128 extending towards the n-type contact electrode 122, and the n-type contact electrode 122 has two conductive fingers 126 extending towards the p-type contact electrode 124.

However, the method of parallel connection for distributing the current cannot achieve a good current spreading effect. Usually, the current intensity is higher in the area closer to the n-type and the p-type contact electrodes, and the current intensity is smaller in the area farther away from the n-type and the p-type contact electrodes or farther away from the connection area of the n-type and the p-type contact electrodes.

Therefore, referring to FIG. 2, in order to further alleviate the current spreading problem, a technique of forming an LED module 130 having a plurality of micro LED chips, e.g. LED chips 132, 134 on one substrate 146 has been proposed. Two adjacent micro LED chips 132, 134 have a trench 140 therebetween. The trench 140 is filled with an insulating material 142 to electrically isolate the adjacent LED chips 132, 134. In the LED module 130, the LED chips 132, 134 are combined in series. That is to say, the n-type contact electrode 136 of the LED chip 132 and the p-type contact electrode 138 of the LED chip 134 are connected by a conductive wire 144.

In the driving mode that a plurality of micro LED chips is connected in series, the micro LED chips may be used to increase the light-emitting area of the entire module, thereby improving the luminance of the LED module. Since the LED module is formed by a plurality of micro LED chips connected in series, a small current (high voltage) is used to drive the LED module. In this manner, the non-uniform current spreading problem of the large LED chip can be solved, and a small current driving manner can be adopted to avoid the efficiency droop phenomenon caused by high current driving.

However, in this LED module design, since an electrical insulating trench needs to be formed between two adjacent LED chips, an epitaxial layer between the adjacent LED chips on the substrate must be removed by etching. Therefore, the time of etching is extended, which increases the requirements for the processing equipment and the manufacturing cost.

Therefore, a heretofore unaddressed need exists in the art to address the aforementioned deficiencies and inadequacies.

### SUMMARY OF THE INVENTION

Accordingly, an aspect of the present invention is directed to an LED device and method for manufacturing the same, in which the LED device includes a plurality of micro light-emitting structures connected in series, so that the non-uniform current spreading problem caused by the large chip dimension can be solved, and a small current driving manner can be adopted to avoid the efficiency droop effect caused by high current driving.

Another aspect of the present invention is directed to an LED device and method for manufacturing the same, in which a current blocking layer is disposed, which can effectively prevent the current from flowing through the undoped semiconductor layer below the current blocking layer when the LED device is operating, thereby ensuring the effective operation of the LED.

Still another aspect of the present invention is directed to an LED device and method for manufacturing the same, in which a preset etching stop layer is used to stop etching at the etching stop layer without completely etching the undoped semiconductor layer. Therefore, the time of the etching process can be reduced and the etching depth can be accurately controlled.

Yet another aspect of the present invention is directed to an LED device and method for manufacturing the same, which can reduce the time for etching and further lower the equipment requirements and reduce the manufacturing cost.

A further aspect of the present invention is directed to an LED device and method for manufacturing the same, in which the current blocking layer may include an undoped AlGaN layer or a super lattice structure, and the undoped AlGaN layer or the super lattice structure may serve as a dislocation blocking layer used in the epitaxy of the semiconductor layer. Therefore, the epitaxy quality of the semiconductor layer that is grown in the follow-up processes can be improved.

In one aspect of the present invention, an LED device is provided. The LED device includes a substrate, an undoped semiconductor layer, a current blocking structure, a plurality of light-emitting structures, a plurality of insulating spacers and a plurality of conductive wires. The undoped semiconductor layer is disposed on the substrate. The current blocking structure is disposed on the undoped semiconductor layer. The light-emitting structures are separately disposed on the current blocking structure. Here, each of the light-emitting structures includes a first conductivity type semiconductor layer, an active layer, a second conductivity type semiconductor layer, and a first electrode and a second electrode. The first conductivity type semiconductor layer and the second conductivity type semiconductor layer have different conductivity types. The active layer is located on a part of the first conductivity type semiconductor layer. The second conductivity type semiconductor layer is located on the active layer. The first electrode and the second electrode are respectively located on the other part of the first conductivity type semiconductor layer and the second conductivity type semiconductor layer. The insulating spacers are respectively located between the adjacent light-emitting structures. The conductive wires respectively connect the first electrode of one of the adjacent light-emitting structures and the second electrode of the other light-emitting structure in sequence.

According to an embodiment of the present invention, the current blocking structure may include a lightly-doped semiconductor layer, and a doping concentration of the lightly-doped semiconductor layer ranges from 8×10¹⁶ cm⁻³ to 8×10¹⁷ cm⁻³. In an example, a thickness of the lightly-doped semiconductor layer ranges from 0.01 μm to 3 μm.

According to another embodiment of the present invention, a material of the first conductivity type semiconductor layer, the active layer and the second conductivity type semiconductor layer is a nitride semiconductor material, and the current blocking structure includes an undoped AlGaN layer.

According to still another embodiment of the present invention, the current blocking structure includes a super lattice structure.

According to yet another embodiment of the present invention, the current blocking structure includes a Mg-doped semiconductor layer, and the first conductivity type semiconductor layer is n-type and the second conductivity type semiconductor layer is p-type.

In another aspect of the present invention, a method for manufacturing an LED device is further provided, which includes the following steps. A substrate is provided. An undoped semiconductor layer is formed on the substrate. A current blocking structure is formed on the undoped semiconductor layer. A plurality of light-emitting structures is formed, in which the light-emitting structures are separately located on the current blocking structure. Each of the light-emitting structures includes a first conductivity type semiconductor layer, an active layer, a second conductivity type semiconductor layer, and a first electrode and a second electrode. The first conductivity type semiconductor layer and the second conductivity type semiconductor layer have different conductivity types. The active layer is located on a part of the first conductivity type semiconductor layer. The second conductivity type semiconductor layer is located on the active layer. The first electrode and the second electrode are respectively located on the other part of the first conductivity type semiconductor layer and the second conductivity type semiconductor layer. A plurality of insulating spacers respectively located between the adjacent light-emitting structures is formed. A plurality of conductive wires respectively connecting the first electrode of one of the adjacent light-emitting structures and the second electrode of the other light-emitting structure in sequence is formed.

According to an embodiment of the present invention, the step of forming the light-emitting structures includes the following steps. A first conductivity type semiconductor material layer, an active material layer and a second conductivity type semiconductor material layer stacked in sequence on the current blocking structure are formed. A part of the second conductivity type semiconductor material layer and a part of the active material layer are removed to expose a part of the first conductivity type semiconductor material layer and form the active layers and the second conductivity type semiconductor layers. The first electrodes and the second electrodes are formed. A part of the exposed part of the first conductivity type semiconductor material layer is removed to form a plurality of separate trenches in the first conductivity type semiconductor material layer and the current blocking structure so as to form the first conductivity type semiconductor layers.

According to another embodiment of the present invention, a material of the first conductivity type semiconductor layer, the active layer and the second conductivity type semiconductor layer is a nitride semiconductor material, and the current blocking structure includes an undoped AlGaN layer. In an example, the step of forming the current blocking structure further includes forming a lightly-doped semiconductor layer or another first conductivity type semiconductor layer on the undoped semiconductor layer.

According to still another embodiment of the present invention, the current blocking structure includes a super lattice structure. In an example, the step of forming the current blocking structure further includes forming a lightly-doped semiconductor layer or another first conductivity type semiconductor layer on the undoped semiconductor layer.

According to yet another embodiment of the present invention, the current blocking structure includes a Mg-doped semiconductor layer, and the Mg-doped semiconductor layer is p-type, the first conductivity type semiconductor layer is n-type, and the second conductivity type semiconductor layer is p-type. In an example, the step of forming the current blocking structure further includes forming a lightly-doped semiconductor layer or another first conductivity type semiconductor layer on the undoped semiconductor layer.

In another aspect of the present invention, the current blocking layer is arranged to successfully connect a plurality of micro light-emitting structures in series, thus forming a large LED device. Therefore, the non-uniform current spreading problem caused by the large chip dimension can be solved, and a small current driving manner can be adopted to avoid the efficiency droop effect caused by high current driving.

Furthermore, in another aspect of the present invention, a preset etching stop layer is used to stop etching at the etching stop layer without completely etching the undoped semiconductor layer. Therefore, the time of the etching process can be reduced and the etching depth can be accurately controlled. Further, the equipment requirements are lowered and the manufacturing cost is reduced.

Moreover, in yet another aspect of the present invention, the current blocking layer may include an undoped AlGaN layer or a super lattice structure, and the undoped AlGaN layer or the super lattice structure may serve as a dislocation blocking layer used in the epitaxy of the semiconductor layer. Therefore, the epitaxy quality of the semiconductor layer that is grown in the follow-up processes can be improved.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1A is a top view of an LED chip in related art;

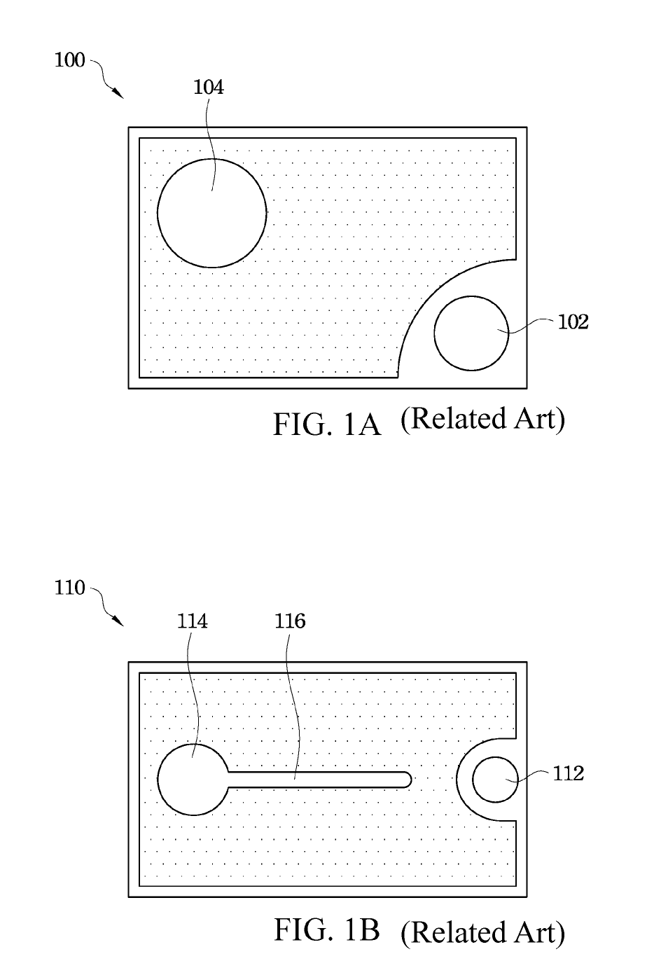

FIG. 1B is a top view of another LED chip in related art;

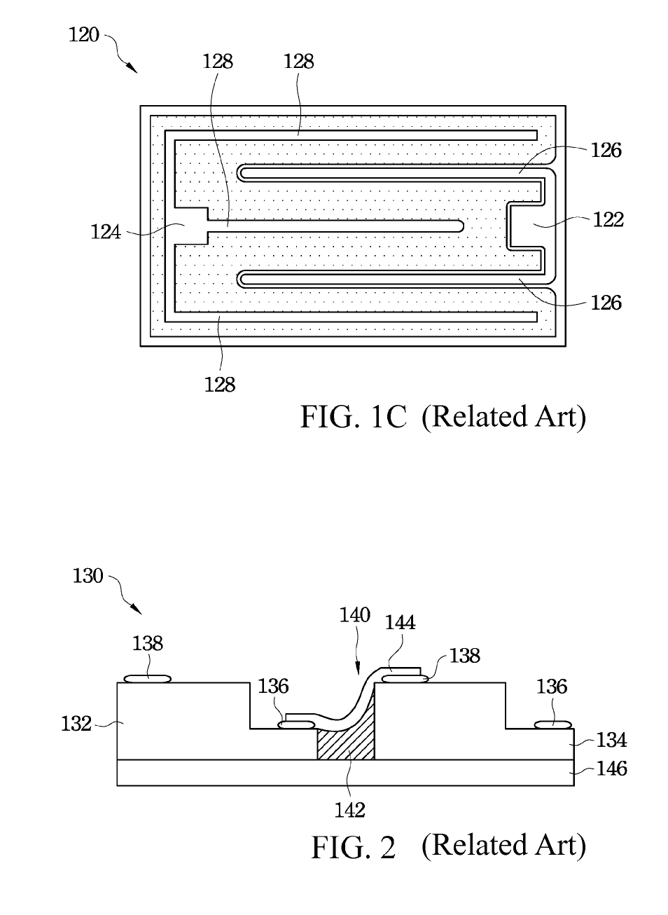

FIG. 1C is a top view of still another LED chip in related art;

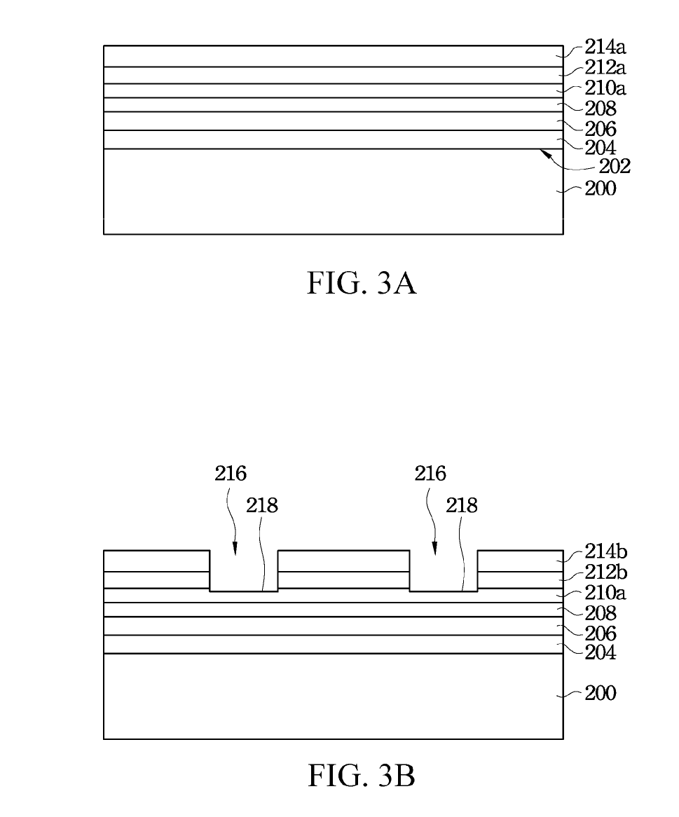

FIG. 2 is a schematic sectional view of an LED module in related art;

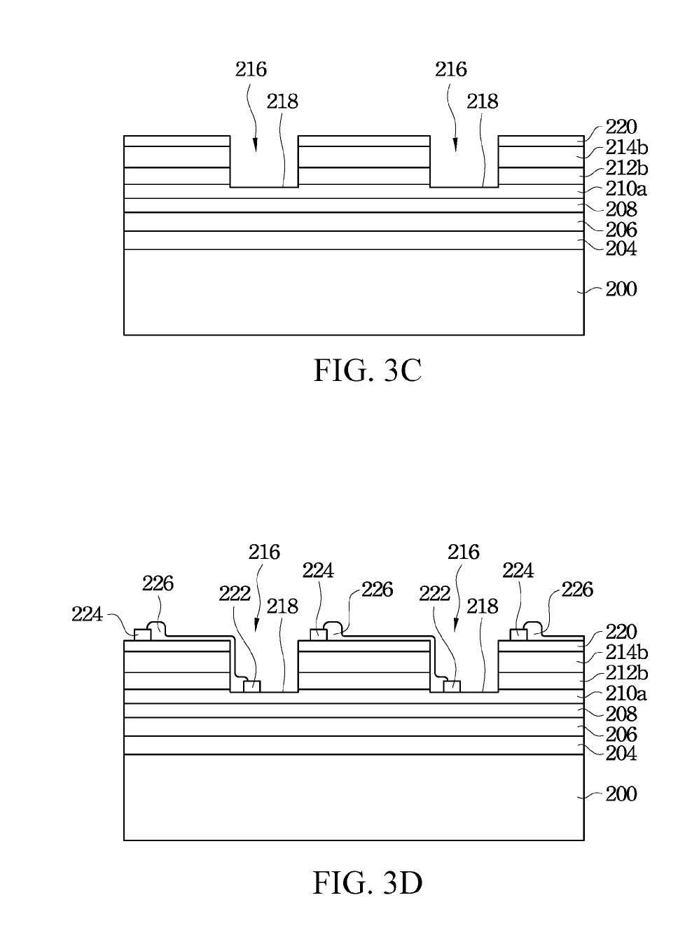

FIG. 3A to FIG. 3F are sectional views illustrating processes of an LED device according to an embodiment of the present invention; and

FIG. 4 is a schematic top view of an LED device according to another embodiment of the present invention.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise

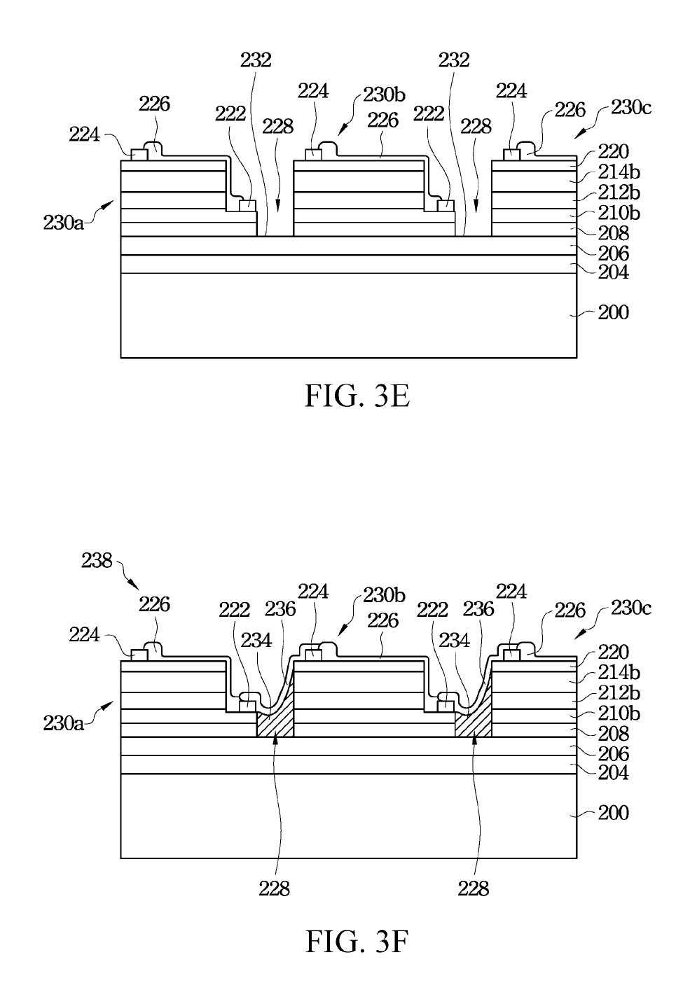

FIG. 3F is a sectional view of an LED device according to an embodiment of the present invention. In this embodiment, the LED device 238 mainly includes a substrate 200, an undoped semiconductor layer 204, a current blocking structure formed by a lightly-doped semiconductor layer 206 and a current blocking layer 208, and a plurality of light-emitting structures 230a, 230b and 230c separately disposed on the current blocking structure. An insulating spacer 234 is disposed between any adjacent two of the light-emitting structures 230a, 230b and 230c, so as to electrically isolate the adjacent light-emitting structures 230a, 230b and 230c. The LED device 238 further includes a plurality of conductive wire 236 to electrically connect the light-emitting structures 230a, 230b and 230c in series. Therefore, the LED device 238 is equivalent to using a structure of a plurality of LED chips having small chip dimensions connected in series, so that the non-uniform current spreading problem caused by the large chip dimension can be solved, and a small current driving manner can be adopted to avoid the efficiency droop effect caused by high current driving.

FIG. 3A to FIG. 3F are sectional views illustrating processes of an LED device according to an embodiment of the present invention. In this embodiment, when the LED device is manufactured, a substrate 200 is firstly provided for growing an epitaxial layer on a surface 202 thereof. In an embodiment, the substrate 200 may be a sapphire substrate.

Then, as shown in FIG. 3A, an undoped semiconductor layer 204, a lightly-doped semiconductor layer 206, a current blocking layer 208, a first conductivity type semiconductor material layer 210a, an active material layer 212a and a second conductivity type semiconductor material layer 214a are grown in sequence on the surface 202 of the substrate 200 by an epitaxy technique such as Metal-Organic Chemical Vapor Deposition (MOCVD) or Molecular Beam Epitaxy. In the present invention, the first conductivity type and the second conductivity type are different conductivity types. For example, one of the first conductivity type and the second conductivity type is n-type, and the other is p-type. In this exemplary embodiment, the first conductivity type is n-type and the second conductivity type is p-type.

In an embodiment, a material of the undoped semiconductor layer 204, the lightly-doped semiconductor layer 206, the first conductivity type semiconductor material layer 210a, the active material layer 212a and the second conductivity type semiconductor material layer 214a may be a nitride semiconductor material, for example, GaN, AlGaN, InGaN, AlInGaN and AlInN semiconductor materials or the like. The active material layer may for example include a multiple quantum well (MQW) structure. A material of the lightly-doped semiconductor layer 206 and the first conductivity type semiconductor material layer 210a may be for example a Si-doped semiconductor material. In an example, the doping concentration of the lightly-doped semiconductor layer 206 for example ranges from about 8×10¹⁶ cm⁻³ to about 8×10¹⁷ cm⁻³, and the doping concentration of the first conductivity type semiconductor material layer 210a for example ranges from about 5×10¹⁸ cm⁻³ to about 2×10¹⁹ cm⁻³.

In an exemplary embodiment, the lightly-doped semiconductor layer 206 may directly serve as the current blocking structure of the LED device. Therefore, in this embodiment, it is not necessary to additionally form the current blocking layer 208. In this case, the lightly-doped semiconductor layer 206 preferably has a small thickness. In some examples, the thickness of the lightly-doped semiconductor layer 206 preferably ranges from 0.01 μm to 3 μm, and more preferably ranges from 0.1 μm to 1 μm. In this embodiment, the doping concentration and the thickness of the lightly-doped semiconductor layer 206 are reduced to increase the resistance of the lightly-doped semiconductor layer 206, so that the driving current will not flow through the lightly-doped semiconductor layer 206. In this manner, the adjacent light-emitting structures are prevented from being electrically conducted by the lightly-doped semiconductor layer 206. In this exemplary embodiment, the lightly-doped semiconductor layer 206 may also serve as an etching stop layer used in the follow-up process of etching separate trenches.

In another exemplary embodiment, the current blocking layer 208 may directly serve as the current blocking structure of the LED device, and in this case, it is not necessary to additionally form the lightly-doped semiconductor layer 206. That is to say, the LED device may include at least one of the lightly-doped semiconductor layer 206 and the current blocking layer 208. Evidently, as shown in FIG. 3A, in this embodiment, the current blocking structure of the LED device may include both the lightly-doped semiconductor layer 206 and the current blocking layer 208. It should be noted that another first conductivity type semiconductor layer may be adopted to replace the lightly-doped semiconductor layer 206 in the current blocking structure having both the lightly-doped semiconductor layer 206 and the current blocking layer 208. In some examples, the thickness of the lightly-doped semiconductor layer 206 or the other first conductivity type semiconductor layer preferably ranges from 0.01 μm to 3 μm, and more preferably ranges from 0.1 μm to 1 μm.

In an embodiment, the material of the first conductivity type semiconductor material layer 210a, the active material layer 212a and the second conductivity type semiconductor material layer 214a is a nitride semiconductor material, and the current blocking layer 208 may include an undoped AlGaN layer. Since AlGaN layer is a high bandgap energy material, the use of undoped AlGaN as the material of the current blocking layer 208 may effectively prevent the driving current from flowing through the undoped semiconductor layer 204 below the current blocking layer 208 via the undoped AlGaN layer. Furthermore, as the materials of the undoped AlGaN layer and the undoped semiconductor layer 204 below the undoped AlGaN layer have different lattice constant, the epitaxy defect of the undoped semiconductor layer 204 can be prevented to progress upwards and meanwhile the quality of the epitaxial layer above the undoped semiconductor layer 204 can be improved. In this embodiment, the current blocking layer 208 may also serve as an etching stop layer used in the follow-up process of etching separate trenches.

In another embodiment, the current blocking layer 208 may include a super lattice structure. The super lattice structure may be for example an alternate stacking structure of Alₓ₁In_{y1}Ga_{1-x1-y1}N and Alₓ₂In_{y2}Ga_{1-x2-y2}N, where x1>x2. In an example, the super lattice structure is formed by stacking a plurality of AlGaN/GaN stack structures. In another example, the super lattice structure may be formed by stacking a plurality of InGaN/GaN stack structures. In this embodiment, the current blocking layer 208 may also serve as an etching stop layer used in the follow-up process of etching separate trenches.

In still another embodiment, when the first conductivity type semiconductor material layer 210a is n-type and the second conductivity type semiconductor material layer 214a is p-type, the current blocking layer 208 may include a Mg-doped semiconductor layer, in which the Mg-doped semiconductor layer is p-type. Therefore, in this embodiment, the first conductivity type semiconductor material layer 210a and the current blocking layer 208 may form a reverse diode structure. The reverse diode structure may provide a current blocking to prevent the adjacent light-emitting structures from being electrically conducted by the current blocking layer 208. In this embodiment, the current blocking layer 208 may also serve as an etching stop layer used in the follow-up process of etching separate trenches. In an example, the material of the first conductivity type semiconductor material layer 210a, the active material layer 212a and the second conductivity type semiconductor material layer 214a is a nitride semiconductor material, and the material of the Mg-doped semiconductor layer is a Mg-doped nitride semiconductor material.

Then, a mesa pattern of the light-emitting structure is defined by for example lithography and etching process. In the step of defining the mesa pattern, a part of the second conductivity type semiconductor material layer 214a and a part of the active material layer 212a are removed to form a plurality of trenches 216 and expose a part 218 of the first conductivity type semiconductor material layer 210a therebelow. As shown in FIG. 3B, after the step of defining the mesa pattern, the partially removed second conductivity type semiconductor material layer 214a and active material layer 212a respectively form a plurality of active layers 212b and second conductivity type semiconductor layers 214b. In an example, in the step of defining the mesa pattern, no part of the first conductivity type semiconductor material layer 210a is removed. However, in other examples, in order to ensure that the active material layer 212a in the trench 216 is completely removed in the etching step, in the step of defining the mesa pattern, usually an upper part of the first conductivity type semiconductor material layer 210a is removed, as shown in FIG. 3B.

It should be noted that in the embodiment as shown in FIG. 3B, two light-emitting structures are taken as the example for illustrating the embodiment of FIG. 3B. However, in practical applications, one LED device may include more than two light-emitting structures. The scope of the present invention is not limited to the embodiments as shown in FIG. 3A to FIG. 3B.

After the mesa of the light-emitting structure is defined, according to the product requirements, for example, a physical vapor deposition (PVD) or an electron beam evaporation technique is selectively adopted to deposit a transparent conductive material layer to cover the exposed second conductivity type semiconductor layer 214b, active layer 212b and first conductivity type semiconductor material layer 210a. Then, a lithography and etching technique is adopted to remove an excessive part of the transparent conductive material layer so as to form a transparent conductive layer (TCL) 220 on each second conductivity type semiconductor layer 214b. The material of the transparent conductive layer 220 may be for example ITO or ZnO. In some examples, for example, a high temperature oven may be adopted to carry out an annealing process, thereby improving the transparency and conductivity of the transparent conductive layer 220.

Then, for example, a lithography and lift-off process or a lithography and etching process is adopted to form a plurality of electrodes 222 on a part of the first conductivity type semiconductor material layer 210a exposed by the trench 216 and form a plurality of electrodes 224 on a part of the transparent conductive layer 220 on the second conductivity type semiconductor layer 214b. Each electrode 222 may be at least corresponding to one electrode 224. In an embodiment, when the LED device does not include the transparent conductive layer 220, the electrode 224 may be directly formed on the second conductivity type semiconductor layer 214b. The material of the electrodes 222 and 224 may be a metal material such as Ni/Au, Cr/Au, TiW/Ti that can form a good ohmic contact with the contact surface, i.e. the first conductivity type semiconductor material layer 210a and the transparent conductive layer 220.

Then, according to the product requirements, an insulating protective material may be selectively formed to cover the exposed transparent conductive layer 220, second conductivity type semiconductor layer 214b, active layer 212b, first conductivity type semiconductor material layer 210a, electrodes 222 and 224. Afterwards, the lithography and etching technique is adopted to remove an excessive part of the insulating protective material so as to expose the electrodes 222 and 224 and a part of the first conductivity type semiconductor material layer 210a in the trench 216, thus forming a plurality of insulating protective layers 226. As shown in FIG. 3D, the insulating protective layers 226 protect the transparent conductive layer 220, the second conductivity type semiconductor layer 214b, the active layer 212b and the first conductivity type semiconductor material layer 210a between the electrode 224 and the corresponding electrode 222. In some examples, the material of the insulating protective layer 226 may be for example SiO₂ or SiN₃.

Then, a dry etching process, for example, an inductively coupled plasma (ICP) etching process, is adopted to remove a part of the exposed part 218 of the first conductivity type semiconductor material layer 210a so as to form a plurality of separate trenches 228 and a plurality of light-emitting structures 230a, 230b and 230c partitioned by the separate trenches 228 in the first conductivity type semiconductor material layer 210a and the current blocking layer 208. Therefore, the light-emitting structures 230a, 230b and 230c are separately located on the current blocking structure 208. The partially removed first conductivity type semiconductor material layer 210a forms a plurality of first conductivity type semiconductor layers 210b.

In each light-emitting structure, for example, in the light-emitting structures 230a and 230b as shown in FIG. 3E, the active layer 212b and the second conductivity type semiconductor layer 214b are stacked in sequence on a part of the first conductivity type semiconductor layer 210b. Furthermore, the light-emitting structures 230a and 230b may be equivalent to a light-emitting structure of a micro LED chip.

In an embodiment, when the current blocking structure only includes the lightly-doped semiconductor layer 206, in the process of etching the separate trenches 228, the lightly-doped semiconductor layer 206 may serve as an etching stop layer to stop etching at the lightly-doped semiconductor layer 206. Therefore, in the separate trenches 228, the lightly-doped semiconductor layer 206 is not completely removed by etching, and still a part of the lightly-doped semiconductor layer 206 is left. To prevent the adjacent light-emitting structures from being electrically conducted by the lightly-doped semiconductor layer 206, the doping concentration and thickness of the lightly-doped semiconductor layer 206 may be reduced to increase the resistance of the lightly-doped semiconductor layer 206.

In another embodiment, when the current blocking structure includes both the lightly-doped semiconductor layer 206 and the current blocking layer 208, in the process of etching the separate trenches 228, the current blocking layer 208 or the lightly-doped semiconductor layer 206 may serve as an etching stop layer to stop etching at the current blocking layer 208 or the lightly-doped semiconductor layer 206. Therefore, in an embodiment, as shown in FIG. 3E, in the separate trenches 228, the current blocking layer 208 is completely removed to expose a part 232 of the lightly-doped semiconductor layer 206, but the lightly-doped semiconductor layer 206 is not etched. In another embodiment, in the separate trenches 228, the current blocking layer 208 is completely removed, and the lightly-doped semiconductor layer 206 is partially removed, but still a part of the lightly-doped semiconductor layer 206 is left. In still another embodiment, in the separate trenches 228, the current blocking layer 208 is partially removed without exposing any part of the lightly-doped semiconductor layer 206. In this case, the current blocking layer 208 left at the bottom of the separate trenches 228 does not affect the characteristics of the device.

In one embodiment of the present invention, when the material of the current blocking layer 208 is the undoped AlGaN, the super lattice structure or the Mg-doped semiconductor layer, the thickness of the material layers are quite small, for example, the thickness of the undoped AlGaN layer ranges from about 10 Å to 1000 Å, the thickness of the super lattice structure ranges from about 10 Å to 1000 Å, and the thickness of the Mg-doped semiconductor layer ranges from about 20 Å to 1000 Å. Therefore, when the separate trenches 228 are formed, the undoped AlGaN layer, the super lattice structure and the Mg-doped semiconductor layer in the separate trenches 228 are easily completely removed by etching.

In a preferred embodiment, when the ICP etching process is adopted to form the separate trenches 228, as the ICP etching machine has a mechanism of detecting etching reactants, the etching depth can be controlled. For example, the material of the current blocking layer 208 is the undoped AlGaN or a super lattice structure of AlGaN/GaN, if the ICP etching machine detects that the reaction products contain Al atoms during the etching, it indicates that the current blocking layer 208 is etched. For another example, when the material of the current blocking layer 208 is the Mg-doped semiconductor layer, if the ICP etching machine detects that the reaction products contain Mg atoms during the etching, it indicates that the current blocking layer 208 is etched. After the etching proceeds to the current blocking layer 208, a preset time of etching is then set to be an etching end, so as to avoid incomplete etching of the first conductivity type semiconductor material layer 210a in the separate trenches 228.

After the separate trenches 228 are fabricated, an insulating material is filled in the separate trenches 228. For example, the insulating material such as an insulating photoresist material is filled in the separate trenches 228 by coating, and then the lithography process is used to remove an excessive part of the insulating photoresist material, so that the insulating spacers 234 are formed in the separate trenches 228 between the adjacent light-emitting structures 230a and 230b and between the adjacent light-emitting structures 230b and 230c.

Then, a plurality of conductive wires 236 is formed by for example physical vapor deposition and lithography and etching to electrically connect the light-emitting structures 230a, 230b and 230c, and thus the fabrication of the LED device 238 is substantially finished. The material of the conductive wire 236 may be a high electrical conductivity material such as aluminum, copper, gold and silver. As shown in FIG. 3F, the conductive wires 236 respectively connect the electrode 222 of the light-emitting structure 230a to the adjacent electrode 224 of the light-emitting structure 230b, and connect the electrode 222 of the light-emitting structure 230b to the adjacent electrode 224 of the light-emitting structure 230c, so as to connect the light-emitting structures 230a, 230b and 230c in series.

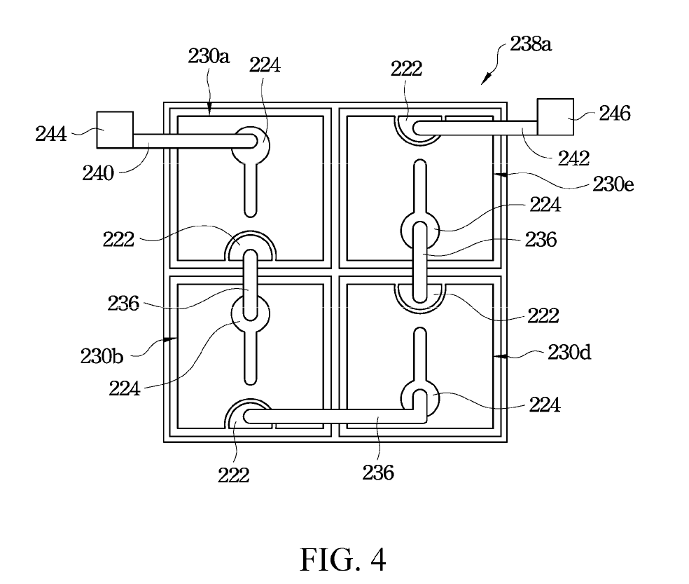

FIG. 4 is a schematic top view of an LED device according to another embodiment of the present invention. The LED device 238a includes four light-emitting structures 230a, 230b, 230d and 230e equivalent to the micro LED chips. A second conductivity type electrode 244 of an external power source is electrically connected to an electrode 224 of a light-emitting structure 230a by a conductive wire 240. An electrode 222 of the light-emitting structure 230a is electrically connected to an electrode 224 of a next light-emitting structure 230b by a conductive wire 236. An electrode 222 of the light-emitting structure 230b is electrically connected to an electrode 224 of a next light-emitting structure 230d by the conductive wire 236. Then, an electrode 222 of the light-emitting structure 230d is electrically connected to an electrode 224 of a next light-emitting structure 230e by the conductive wire 236. Finally, an electrode 222 of the light-emitting structure 230e is electrically connected to a first conductivity type electrode 246 of the external power source by a conductive wire 242. Therefore, the LED device 238a includes four light-emitting structures 230a, 230b, 230d and 230e connected in series.

It can be seen from the embodiments that, among other things, an advantage of the present invention lies in that the LED device of the present invention includes a plurality of micro light-emitting structures connected in series, so that the non-uniform current spreading problem caused by the large chip dimension can be solved, and a small current driving manner can be adopted to avoid the efficiency droop effect caused by high current driving.

It can be seen from the embodiments that, among other things, another advantage of the present invention lies in that the LED device of the present invention has the current blocking layer, which can effectively prevent the current from flowing through the undoped semiconductor layer below the current blocking layer when the LED device is operating, thereby ensuring the effective operation of the LED.

It can be seen from the embodiments that, among other things, still another advantage of the present invention lies in that the method for manufacturing an LED device of the present invention adopts a preset etching stop layer to stop etching at the etching stop layer without completely etching the undoped semiconductor layer. Therefore, the time of the etching process can be reduced and the etching depth can be accurately controlled.

It can be seen from the embodiments that, among other things, yet another advantage of the present invention lies in that the method for manufacturing an LED device of the present invention can reduce the etching time, and further lower the equipment requirements and reduce the manufacturing cost.

It can be seen from the embodiments that, among other thins, a further advantage of the present invention lies in that the current blocking layer may include an undoped AlGaN layer or a super lattice structure, and the undoped AlGaN layer or the super lattice structure may serve as a dislocation blocking layer used in the epitaxy of the semiconductor layer. Therefore, the method for manufacturing an LED device of the present invention can improve the epitaxy quality of the semiconductor layer that is grown in the follow-up process.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light-emitting diode (LED) device, comprising:
a substrate;
an undoped semiconductor layer, disposed on the substrate;
a current blocking structure, disposed on the undoped semiconductor layer;
a plurality of light-emitting structures, separately disposed on the current blocking structure, wherein each of the light-emitting structures comprises:
a first conductivity type semiconductor layer;
an active layer, located on a part of the first conductivity type semiconductor layer;
a second conductivity type semiconductor layer, located on the active layer, wherein the first conductivity type semiconductor layer and the second conductivity type semiconductor layer have different conductivity types; and
a first electrode and a second electrode, respectively located on the other part of the first conductivity type semiconductor layer and the second conductivity type semiconductor layer;
a plurality of insulating spacers, respectively located between the adjacent light-emitting structures; and
a plurality of conductive wires, respectively connecting the first electrode of one of the adjacent light-emitting structures and the second electrode of the other light-emitting structure in sequence.

2. The LED device according to claim 1, wherein the current blocking structure comprises a lightly-doped semiconductor layer, and a doping concentration of the lightly-doped semiconductor layer ranges from 8×10¹⁶ cm⁻³ to 8×10¹⁷ cm⁻³.

3. The LED device according to claim 2, wherein a thickness of the lightly-doped semiconductor layer ranges from 0.01 μm to 3 μm.

4. The LED device according to claim 1, wherein a material of the first conductivity type semiconductor layer, the active layer and the second conductivity type semiconductor layer is a nitride semiconductor material, and the current blocking structure comprises an undoped AlGaN layer.

5. The LED device according to claim 4, wherein the current blocking structure further comprises a lightly-doped semiconductor layer or another first conductivity type semiconductor layer between the undoped AlGaN layer and the undoped semiconductor layer.

6. The LED device according to claim 5, wherein a thickness of the lightly-doped semiconductor layer or the other first conductivity type semiconductor layer ranges from 0.01 μm to 3 μm.

7. The LED device according to claim 1, wherein the current blocking structure comprises a super lattice structure.

8. The LED device according to claim 7, wherein the super lattice structure is an alternate stacking structure of Alₓ₁In_{y1}Ga_{1-x1-y1}N and Alₓ₂In_{y2}Ga_{1-x2-y2}N, where x1>x2.

9. The LED device according to claim 7, wherein the current blocking structure further comprises a lightly-doped semiconductor layer or another first conductivity type semiconductor layer between the super lattice structure and the undoped semiconductor layer.

10. The LED device according to claim 9, wherein a thickness of the lightly-doped semiconductor layer or the other first conductivity type semiconductor layer ranges from 0.01 μm to 3 μm.

11. The LED device according to claim 1, wherein the current blocking structure comprises a Mg-doped semiconductor layer, and the first conductivity type semiconductor layer is n-type and the second conductivity type semiconductor layer is p-type.

12. The LED device according to claim 11, wherein a material of the first conductivity type semiconductor layer, the active layer and the second conductivity type semiconductor layer is a nitride semiconductor material, and a material of the Mg-doped semiconductor layer is a Mg-doped nitride semiconductor material.

13. The LED device according to claim 11, wherein the current blocking structure further comprises a lightly-doped semiconductor layer or another first conductivity type semiconductor layer between the Mg-doped semiconductor layer and the undoped semiconductor layer.

14. A method for manufacturing a light-emitting diode (LED) device, comprising:
providing a substrate;
forming an undoped semiconductor layer on the substrate;
forming a current blocking structure on the undoped semiconductor layer;
forming a plurality of light-emitting structures, wherein the light-emitting structures are separately located on the current blocking structure and each of the light-emitting structures comprises:
a first conductivity type semiconductor layer;
an active layer, located on a part of the first conductivity type semiconductor layer;
a second conductivity type semiconductor layer, located on the active layer, wherein the first conductivity type semiconductor layer and the second conductivity type semiconductor layer have different conductivity types; and
a first electrode and a second electrode, respectively located on the other part of the first conductivity type semiconductor layer and the second conductivity type semiconductor layer;
forming a plurality of insulating spacers respectively located between the adjacent light-emitting structures; and
forming a plurality of conductive wires respectively connecting the first electrode of one of the adjacent light-emitting structures and the second electrode of the other light-emitting structure in sequence.

15. The method for manufacturing an LED device according to claim 14, wherein the step of forming the light-emitting structures comprises:
forming a first conductivity type semiconductor material layer, an active material layer and a second conductivity type semiconductor material layer stacked in sequence on the current blocking structure;
removing a part of the second conductivity type semiconductor material layer and a part of the active material layer to expose a part of the first conductivity type semiconductor material layer and form the active layers and the second conductivity type semiconductor layers;
forming the first electrodes and the second electrodes; and
removing a part of the exposed part of the first conductivity type semiconductor material layer to form a plurality of separate trenches in the first conductivity type semiconductor material layer and the current blocking structure so as to form the first conductivity type semiconductor layers.

16. The method for manufacturing an LED device according to claim 14, wherein the current blocking structure comprises a lightly-doped semiconductor layer, and a doping concentration of the lightly-doped semiconductor layer ranges from 8×10¹⁶ cm⁻³ to 8×10¹⁷ cm⁻³.

17. The method for manufacturing an LED device according to claim 16, wherein a thickness of the lightly-doped semiconductor layer ranges from 0.01 μm to 3 μm.

18. The method for manufacturing an LED device according to claim 14, wherein a material of the first conductivity type semiconductor layer, the active layer and the second conductivity type semiconductor layer is a nitride semiconductor material, and the current blocking structure comprises an undoped AlGaN layer.

19. The method for manufacturing an LED device according to claim 18, wherein the step of forming the current blocking structure further comprises forming a lightly-doped semiconductor layer or another first conductivity type semiconductor layer on the undoped semiconductor layer.

20. The method for manufacturing an LED device according to claim 19, wherein a thickness of the lightly-doped semiconductor layer or the other first conductivity type semiconductor layer ranges from 0.01 μm to 3 μm.

21. The method for manufacturing an LED device according to claim 14, wherein the current blocking structure comprises a super lattice structure.

22. The method for manufacturing an LED device according to claim 21, wherein the step of forming the current blocking structure further comprises forming a lightly-doped semiconductor layer or another first conductivity type semiconductor layer on the undoped semiconductor layer.

23. The method for manufacturing an LED device according to claim 14, wherein the current blocking structure comprises a Mg-doped semiconductor layer, and the Mg-doped semiconductor layer is p-type, the first conductivity type semiconductor layer is n-type, and the second conductivity type semiconductor layer is p-type.

24. The method for manufacturing an LED device according to claim 23, wherein the step of forming the current blocking structure further comprises forming a lightly-doped semiconductor layer or another first conductivity type semiconductor layer on the undoped semiconductor layer.
